(19) United States
(12) Patent Application Publication
(10) Pub. No.: US 2019/0382883 A1
(43) Pub. Date: Dec. 19, 2019

(54) SUBSTRATE SUPPORTS FOR A SPUTTERING DEVICE

(71) Applicant: Corning Incorporated, Corning, NY (US)

(72) Inventors: Xu Ouyang, Painted Post, NY (US); Ye Guang Pan, Camas, WA (US)

(21) Appl. No.: 16/485,696

(22) PCT Filed: Feb. 7, 2018
(86) PCT No.: PCT/US2018/017166

§ 371 Date: Aug. 13, 2019

Related U.S. Application Data
(60) Provisional application No. 62/458,207, filed on Feb. 13, 2017.

(51) Int. Cl. C23C 14/50; C23C 14/35; C23C 14/58; C03C 17/00; H01J 37/34; H01J 37/32; H05K 5/03; H05K 5/00

(52) U.S. Cl. CPC C23C 14/505; H01J 2237/332; C23C 14/5873; C03C 17/002; H01J 37/3405; H01J 37/32715; H05K 5/03; H05K 5/0017; H01J 37/32779; H01J 37/3417; C03C 2218/154; H01J 37/32513; H01J 2237/2007; H01J 2237/20214; C23C 14/35

(57) ABSTRACT

A sputtering device and method including a chamber, a target disposed within the chamber, and a substrate support including at least a portion consisting essentially of a non-aluminous and non-magnetic metallic material disposed within the chamber. The substrate support may include a carrier and a fixture for holding a substrate. In some embodiments, at least the target-facing surface of the carrier consists essentially of a non-aluminous and non-magnetic metallic material. In some embodiments, the fixture consists essentially of a non-aluminous and non-magnetic metallic material. The sputtering device may be drum sputtering device. The sputtering method may be a magnetron sputtering method.

### CROSS-REFERENCE TO RELATED APPLICATION

This application claims the benefit of priority under 35 U.S.C. § 119 of U.S. Provisional Application Ser. No. 62/458,207 filed on Feb. 13, 2017, the content of which is relied upon and incorporated herein by reference in its entirety.

### BACKGROUND

### Field

The present disclosure relates to sputter coating of a substrate, for example a glass substrate, for example a cover glass. In particular, the present disclosure relates to substrate supports for holding a substrate within a sputtering device, for example a drum sputtering device.

### Background

Sputter deposition is a physical vapor deposition (PVD) method used to deposit thin films of a material on a substrate. Sputtering involves ejecting material from a target, which is a source, onto the substrate, for example a glass substrate.

Glass articles, for example cover glass, such as cover glass for a mobile phone, may be manufactured with one or more surface treatments to enhance its functions and provide a positive experience for an end user. For example, cover glass may be coated with one or more coating layers to provide desired characteristics. Such coating layers include anti-reflection coating layers, easy-to-clean coating layers, and scratch resistant coating layers. These coating layers can be applied on a surface of the cover glass using a sputtering process. The sputtering process used to deposit these coatings layers should create a uniform and defect free coating that provides the desired characteristics.

Therefore, a continuing need exists for innovations in coating layers for glass articles and methods of depositing these coating layers on a surface of the glass articles.

### BRIEF SUMMARY

The present disclosure is directed to substrate supports for holding one or more substrates within a sputtering device, and sputtering devices including one or more of these substrate supports.

Some embodiments are directed towards a sputtering device including a chamber; a target disposed within the chamber; a rotating drum including a drum frame disposed within the chamber; and a substrate support including a carrier coupled to the drum frame and a fixture for holding a substrate, the fixture coupled to a target-facing surface of the carrier, and where at least the target-facing surface of the carrier consists essentially of a non-aluminous and non-magnetic metallic material.

In some embodiments, the sputtering device according to the embodiments of the preceding paragraph may include a carrier that includes a clamp coupled to the target-facing surface of the carrier for clamping the fixture onto the carrier. In some embodiments, the clamp may consist essentially of a non-aluminous and non-magnetic material.

In some embodiments, the embodiments of any of the preceding paragraphs may further include a fixture that consists essentially of a non-aluminous and non-magnetic metallic material.

In some embodiments, the embodiments of any of the preceding paragraphs may include a carrier that consists essentially of a non-aluminous and non-magnetic metallic material.

In some embodiments, the embodiments of any of the preceding paragraphs may include a substrate support that consists essentially of a non-aluminous and non-magnetic metallic material.

In some embodiments, the embodiments of any of the preceding paragraphs may include a carrier where at least the target-facing surface of the carrier consists essentially of stainless steel 316.

In some embodiments, the embodiments of any of the preceding paragraphs may include a substrate support where at least 90 volume percent of the substrate support consists essentially of a non-aluminous and non-magnetic metallic material.

In some embodiments, the embodiments of any of the preceding paragraphs may include a carrier that includes a plate defining the target-facing surface of the carrier. In some embodiments, the plate may be a hollow plate and/or the plate may consist essentially of stainless steel 316 having no magnetic charge. In some embodiments the magnetic charge may be removed by heat treating the stainless steel at a temperature in the range of 600 degrees C. to 1400 degrees C.

In some embodiments, the embodiments of any of the preceding paragraphs may include a fixture that includes a bottom plate and a top plate coupled to the bottom plate for clamping a substrate therebetween, and the top plate and the bottom plate consist essentially of a non-aluminous and non-magnetic metallic material. In some embodiments, the embodiments of any of the preceding paragraphs may include a fixture that includes a vacuum plate having a plurality of through holes and a double sided adhesive layer disposed over a portion of a top surface of the vacuum plate for adhering a substrate thereto, and the vacuum plate consists essentially of a non-aluminous and non-magnetic metallic material.

In some embodiments, the embodiments of any of the preceding paragraphs may include a plurality of fixtures coupled to the target-facing surface of the carrier, at least one fixture for holding at least one substrate, and the carrier includes one or more clamps for clamping the fixtures onto the carrier.

In some embodiments, the embodiments of any of the preceding paragraphs may include a carrier where at least the target-facing surface of the carrier consists essentially of a material selected from the group consisting of: a copper alloy and a titanium alloy.

In some embodiments, the embodiments of any of the preceding paragraphs may include a carrier where at least the target-facing surface of the carrier consists essentially of a material having a coefficient of thermal expansion equal to 21.6 ppm/° C. or less at 20° C.

In some embodiments, the embodiments of any of the preceding paragraphs may include a carrier where at least the target-facing surface of the carrier consists essentially of a material having a coefficient of thermal expansion equal to 18 ppm/° C. or less at 20° C.

In some embodiments, the embodiments of any of the preceding paragraphs may include a carrier that weighs 100 kilograms or less.

Some embodiments may be directed towards a sputtering method including the steps of coupling a substrate to a carrier; coupling the carrier to a rotating drum including a drum frame, the drum frame disposed within a chamber of a sputtering device, the chamber including a target disposed with the chamber; and coating the substrate with a coating layer, where at least a target-facing surface of the carrier consists essentially of a non-aluminous and non-magnetic metallic material having a coefficient of thermal expansion that is equal to 18 ppm/° C. or less at 20° C.

In some embodiments, the sputtering method of the preceding paragraph may be a drum sputtering method.

In some embodiments, the sputtering method of any of the preceding paragraphs may be a magnetron sputtering method.

In some embodiments, the sputtering method of any of the preceding paragraphs may include coupling the substrate to the carrier by coupling the substrate to a fixture and coupling the fixture to the carrier, where the fixture consists essentially of a non-aluminous and non-magnetic metallic material having a coefficient of thermal expansion that is equal to 18 ppm/° C. or less at 20° C.

In some embodiments, the sputtering method of any of the preceding paragraphs may include etching the target-facing surface of the carrier with a strong acid and a strong base to remove coating layer material from the target-facing surface after one or more substrate coating processes.

Some embodiments are directed towards a sputtering device including a chamber; a target disposed within the chamber; a substrate support disposed within the chamber, the substrate support including a carrier and a fixture for holding a substrate, the fixture coupled to a target-facing surface of the carrier, where at least the target-facing surface of the carrier consists essentially of a non-aluminous and non-magnetic metallic material.

Some embodiments are directed towards an article including a coated cover glass, the coated cover glass made by the sputtering method including coupling a cover glass to a carrier; coupling the carrier to a rotating drum including a drum frame, the drum frame disposed within a chamber of a sputtering device, the chamber including a target disposed with the chamber; and coating the cover glass with a coating layer, where at least a target-facing surface of the carrier consists essentially of a non-aluminous and non-magnetic metallic material having a coefficient of thermal expansion that is equal to 18 ppm/° C. or less at 20° C.

In some embodiments, the article according to the preceding paragraph may be a consumer electronic product, the consumer electronic product including a housing having a front surface, a back surface and side surfaces; electrical components provided at least partially within the housing, the electrical components including at least a controller, a memory, and a display, the display being provided at or adjacent the front surface of the housing; and the coated cover glass of the preceding paragraph disposed over the display.

### BRIEF DESCRIPTION OF THE DRAWINGS

The accompanying figures, which are incorporated herein, form part of the specification and illustrate embodiments of the present disclosure. Together with the description, the figures further serve to explain the principles of and to enable a person skilled in the relevant art(s) to make and use the disclosed embodiments. These figures are intended to be illustrative, not limiting. Although the disclosure is generally described in the context of these embodiments, it should be understood that it is not intended to limit the scope of the disclosure to these particular embodiments. In the drawings, like reference numbers indicate identical or functionally similar elements.

FIG. 1 illustrates a sputtering device according to some embodiments.

FIG. 2A illustrates a cross-sectional view of a substrate support and a frame according to some embodiments.

FIG. 2B illustrates a cross-sectional view of a substrate support and a frame according to some embodiments.

FIG. 3A illustrates a fixture for holding at least one substrate according to some embodiments.

FIG. 3B illustrates a cross-sectional view of an aperture of a fixture along the line 3B-3B′ in FIG. 3A according to some embodiments.

FIG. 4 illustrates a fixture assembly according to some embodiments.

FIG. 5 illustrates a substrate support according to some embodiments.

FIG. 6 illustrates a vacuum fixture for holding at least one substrate according to some embodiments.

FIG. 7 illustrates a cross-sectional view along the line 7-7′ in FIG. 6.

FIG. 8 illustrates a plurality of glass substrates fixed to a vacuum fixture according to some embodiments.

FIG. 9 illustrates a vacuum box according to some embodiments.

FIG. 10 illustrates a flow chart of a process for loading substrates into a sputtering device according to some embodiments.

FIG. 11 illustrates a flow chart of a sputter deposition process according to some embodiments.

FIG. 12 illustrates a consumer product according to some embodiments.

### DETAILED DESCRIPTION

The following examples are illustrative, but not limiting, of the present disclosure. Other suitable modifications and adaptations of the variety of conditions and parameters normally encountered in the field, and which would be apparent to those skilled in the art, are within the spirit and scope of the disclosure.

Coating layers for a glass article, for example cover glass, may serve to, among other things, reduce undesired reflections, prevent formation of mechanical defects in the glass (e.g., scratches or cracks), and/or provide an easy to clean transparent surface. The glass articles disclosed herein may be incorporated into another article such as an article with a display (or display articles) (e.g., consumer electronic products, including mobile phones, tablets, computers, navigation systems, wearable devices (e.g., watches) and the like), architectural articles, transportation articles (e.g., automotive, trains, aircraft, sea craft, etc.), appliance articles, or any article that may benefit from some transparency, scratch-resistance, abrasion resistance, or a combination thereof. An exemplary article incorporating any of the glass articles disclosed herein is a consumer electronic device including a housing having front, back, and side surfaces; electrical components that are at least partially inside or entirely within the housing and including at least a controller, a memory, and a display at or adjacent to the front surface of the housing; and a cover substrate at or over the front surface of the housing such that it is over the display. In some embodiments, the cover substrate may include any of the glass articles disclosed herein. In some embodiments, at least one of a portion of the housing or the cover glass comprises the glass articles disclosed herein.

Coating layers for a glass article may be deposited using a sputtering deposition process, such a magnetron sputtering. Sputter deposition is a physical vapor deposition (PVD) method of thin film deposition. “Sputtering” involves ejecting particles of material from a “target” (also referred to as a “source”) onto a “substrate” such as a glass article or silicon wafer. Resputtering is re-emission of the deposited material during the deposition process by ion or atom bombardment. “Magnetron sputtering” is a PVD process in which a plasma is created and positively charged ions from the plasma are accelerated by an electrical field (e.g., magnetic field) superimposed on a negatively charged electrode or “target.” The positive ions are accelerated by potentials ranging from a few hundred to a few thousand electron volts and strike the negative electrode with sufficient force to dislodge and eject atoms from the target. These atoms will be ejected in a typical line-of-sight cosine distribution from the face of the target and will condense on surfaces that are placed in proximity to the magnetron sputtering cathode.

Sputtering of materials onto various substrates, including onto glass substrates, allows for the deposition of thin films (coating layers) with a high degree of control over the resulting thickness of the film. One type of sputtering system is a rotary drum sputter system designed to sputter onto a plurality of substrates. In such a system, substrates may be secured to fixtures that are in-turn secured to larger substrate carriers. The substrate carriers may then be removably coupled to a frame of a rotating drum that rotates during deposition of a coating layer. As the frame rotates, the substrates are sequentially exposed to different conditions. As the substrates pass by targets, particles from the targets may be sputtered onto the substrates. The substrates may optionally pass through a reactive gas or plasma region and/or an inert gas region where sputtered particles are not being deposited. Any reactive gas or plasma present in such regions may react with particles previously deposited by sputtering. Oxygen and nitrogen plasma are commonly used to turn sputter deposited metal layers into oxides or nitrides of the metal. Drum sputtering devices may allow for a large number of substrates to be sputter coated in an efficient manner, and are suitable for commercial production of a large number of coated substrates (e.g., coated cover glass articles).

The availability of many parameters that control sputter deposition make it a complex process, but also allow for a large degree of control over the growth and microstructure of a deposited film. While specific sputtering mechanisms are described herein, any suitable sputtering mechanism may be used.

Substrate supports (e.g., carriers and fixtures) within a sputtering chamber should serve to securely hold substrates within the chamber, avoid undesirable physical or chemical interactions with the coating material being deposited on the substrates, and refrain from introducing debris within the sputtering chamber. Substrates supports discussed reduce or eliminate undesirable physical or chemical interactions and minimize the risk of introducing debris within a sputtering chamber. In other words, substrate supports discussed herein have minimal, or no, undesirable effects on a sputter coating deposition process.

In some embodiments, a substrate support may include one or more fixtures to hold one or more substrates and a carrier to hold the fixture(s). In some embodiments, the materials used to make the fixture, the carrier, and any additional components used to hold fixtures within a sputtering chamber, may have properties that avoid undesirable interactions with a coating material being deposited on the substrates and avoid the formation of debris. Undesirable physical and chemical interactions include (i) magnetic interaction with atoms of the coating material traveling from the target to the substrate and (ii) chemical reactions between vapors outgassed from materials of a substrate support and the atoms of the coating material created when a substrate support is heated within the sputtering chamber.

Magnetic interaction between atoms of a coating material and a substrate support may negatively affect the properties of the resulting coating deposited on a substrate. For example, undesirable magnetic interactions, may affect among other things, the location(s) on which a coating layer is deposited, the thickness of the coating layer, the thickness profile of the coating layer, the structural characteristics of the coating layer, and the visual characteristics of the coating layer. Undesirable magnetic interaction may result in 10% to 15% of coating layers depositing during a coating process being mechanically or visually flawed.

In a magnetron sputtering process, undesirable magnetic interaction between substrate support components and ions or atoms may be particularly undesirable because magnetron sputtering relies on a well-controlled electric field (e.g., magnetic field) to produce coated films on a substrate (e.g., films with desired thickness, uniform thickness, and devoid of structural and visual defects). In a magnetron sputtering process, a magnetic field confines electrons and plasma near a cathode to enhance target deposition rate. For a well-designed coating system with uniform coating distribution, extra, extraneous magnetic fields or magnetic field strength near substrates can result in coating abnormalities, such as non-uniform coating thickness, especially for large area coating depositions. Unintended magnetic field(s) near substrates will perturb the incoming path of charged materials in the form of ions and molecules, and cause non-uniform local thicknesses in a coated film.

In some cases, undesirable chemical interaction may be the result of vapors outgassed from an adhesive present with a sputtering chamber. In some cases, adhesives, like double sided tapes, may be used to secure substrates to a fixtures, or fixtures to carriers. Adhesives, such as double sided Kapton® tape, may outgas when heated (e.g., to 200-300 degrees C.) within a sputtering chamber. This outgassing may contaminate the sputtered material being coated on the substrates and create un-removable stains on the substrates due to a chemical reactions between the outgasses and the sputtered material. Outgassing can also reduce the vacuum pumping speed for a sputtering chamber.

Debris can be introduced into a sputtering chamber via, among other things, (i) the fracturing (e.g., cracking) and flaking of coating material deposited on a substrate support during deposition of the coating material on substrates held by the substrate support, (ii) the falling of substrates from a substrate support that failed to adequately secure the substrates and subsequent broken pieces of the substrates, and (iii) debris introduced via human interaction with substrates (e.g., touching) before or during the loading of substrates into the chamber (e.g., while securing substrates to a fixture). Debris, may affect among other things, the location(s) on which a coating layer is deposited, the thickness of the coating layer, the thickness profile of the coating layer, the structural characteristics of the coating layer, and the visual characteristic of the coating layer.

During a sputtering deposition process, elevated temperatures within a sputtering chamber (e.g., to 200-300 degrees C.) may degrade temperature sensitive adhesives present within a chamber. This degradation of the adhesive (e.g., via outgassing of chemical compounds in the adhesive's chemical formula) may cause failure of the adhesive, thereby causing substrates to drop from a substrate support. Substrates that drop from a substrate support may break, create debris within a sputtering chamber, and damage other components of a sputtering device. The chance of degradation and failure of an adhesive may increase the longer a sputtering deposition process lasts.

Debris may also be introduced into a sputtering chamber due to coating material flaking off a substrate support during a sputtering deposition process. During a sputtering deposition process, surfaces proximate to and that face a target at any point in time (i.e., surfaces in the line-of-sight of the face of the target, also called “target-facing surfaces”) may be coated with the coating atoms being ejected from the target. Repeated deposition processes will cause the coating atoms to build up and form a significantly thick coating on the target-facing surfaces. And eventually, the coating may begin to fracture (crack) and flake off the target-facing surfaces, thereby creating debris within a sputtering chamber. Such fracturing and flaking may be accelerated by the thermal cycling of the coating material and substrate support created by heating up the sputtering chamber for deposition and cooling it down between deposition processes.

In some embodiments, substrate supports may include materials and components that avoid the aforementioned physical or chemical interactions with a coating material and refrain from introducing debris within the chamber. In some embodiments, components of a substrate support (e.g., a carrier or a fixture) may be made, in whole or in part, with a non-magnetic metallic material. A non-magnetic metallic material reduces, or prevents entirely, undesirable magnetic interaction between a substrate support and atoms of a coating material being deposited on a substrate. Thus, the coating on the substrate has more uniform properties, e.g., coating thickness.

In some embodiments, components of a substrate support may be composed essentially of (i.e., consist essentially of) one or more non-magnetic metallic materials. In some embodiments, components of a substrate support may be composed entirely of (i.e., consist of) one or more non-magnetic metallic materials. In some embodiments, the entire substrate support (e.g., a carrier and fixture(s)) may be composed essentially of (i.e., consist essentially of) one or more non-magnetic metallic materials. In some embodiments, the entire substrate support (e.g., a carrier and fixture(s)) may be composed entirely of (i.e., consist of) one or more non-magnetic metallic materials. Suitable non-magnetic metallic materials include, but are not limited to 316 stainless steel, aluminum and non-magnetic aluminum alloys, titanium and non-magnetic titanium alloys, and copper and non-magnetic copper alloys.

As used herein, the term “non-magnetic metallic material” means a metallic material that will not magnetically hold a magnet when a surface of a component made of the non-magnetic material and a magnet disposed on that surface are positioned perpendicular to the ground. In some embodiments, a non-magnetic metallic material may be a non-ferrous metallic material. As used herein the term “non-ferrous metallic material” means a metallic material including 1% or less iron by weight. In some embodiments, a non-magnetic metallic material may be a non-magnetic and non-ferritic metal, for example a non-ferritic steel, such as an austenitic stainless steel. As used herein the term “non-ferritic metal” means a metallic material including 1% or less ferrite crystal structure by weight. As used here the term “non-ferritic steel” means a steel including 1% or less ferrite crystal structure by weight.

In some embodiments, components of a substrate support (e.g., a carrier or a fixture) may be made, in whole or in part, with one or more non-magnetic and non-aluminous metallic materials. As used herein a “non-aluminous metallic material” means a metallic material containing 25% or less aluminum by weight. In some embodiments, a non-aluminous material may contain 20% or less aluminum by weight, no more than 15% aluminum by weight, 10% or less aluminum by weight, 5% or less aluminum by weight, 2% or less aluminum by weight, or 1% or less aluminum by weight. As used herein a “metallic material” is crystalline material composed of at least 95% metal by weight.

In some embodiments, components of a substrate support (e.g., a carrier or a fixture) may be made, in whole or in part, with one or more non-magnetic inorganic and non-metallic ceramic materials. In some embodiments, components of a substrate support (e.g., a carrier or a fixture) may be made, in whole or in part, with one or more non-magnetic inorganic and non-metallic ceramic materials having a CTE of 21.6 ppm/° C. or less at 20° C., 18 ppm/° C. or less at 20° C., or 16.2 ppm/° C. or less at 20° C. The linear coefficient of thermal expansion (CTE) over the temperature range 20-300° C. is expressed in terms of ppm/° C. and should be determined using a push-rod dilatometer in accordance with ASTM E228-11. In some embodiments, components of a substrate support may be made, in whole or in part, with one or more non-magnetic high temperature engineering plastics.

In some embodiments, components of a substrate support may be composed essentially of (i.e., consist essentially of) one or more non-magnetic and non-aluminous metallic materials. In some embodiments, components of a substrate support may be composed entirely of (i.e., consist of) one or more non-magnetic and non-aluminous metallic material. In some embodiments, the entire substrate support (e.g., a carrier and fixture(s)) may be composed essentially of (i.e., consist essentially of) one or more non-magnetic and non-aluminous materials. In some embodiments, the entire substrate support (e.g., a carrier and fixture(s)) may be composed entirely of (i.e., consist of) one or more non-magnetic and non-aluminous materials. Suitable non-magnetic and non-aluminous materials include, but are not limited to, 316 stainless steel, titanium and non-aluminous titanium alloys, and copper and non-aluminous copper alloys.

As shown below in Table 1, non-aluminous metallic materials have a lower coefficient of thermal expansion (CTE), at 20° C. (room temperature) compared to aluminous materials. CTE values may be dependent on the temperature at which the values are measured. Unless noted otherwise, throughout the disclosure CTE values reported herein are at 20° C. (room temperature) and are generally applicable over the range of from 20° C. to 300° C. The lower CTE of a non-aluminous metallic material may help reduce the chance of fracturing (cracking), and the subsequent flaking off, of a material coated on a target-facing surface of a substrate support. The lower CTE of a non-aluminous material may reduce the occurrence and/or frequency of fracturing and flaking of a coated material because the lower CTE will be closer to the CTE of typical coating materials for glass articles, such as cover glasses. Typical coating materials for glass articles may have a CTE of less than 12.6 ppm/° C. at 20° C. For example, silicon dioxide may have a CTE in the range of 1.78 to 2.43 ppm/° C. at 20° C. As another example, silicon nitride may have a CTE in the range of 4.54 to 12.0 ppm/° C. at 20° C.

TABLE 1
Coefficients of thermal expansion in micro inch/in° C. (μ inch/in° C.)
(ppm/in° C.) for various metallic materials.

| | |
|---|---|
| Temp | CTE |

Units

| | Range | (μ inch/ |
|---|---|---|
| Metal | (° C.) | (in ° C.)) |
| Admiralty Brass | 20-300 | 20.2 |
| Aluminum | 20-100 | 23.6 |
| Aluminum Bronze | 20-300 | 16.2 |
| Aluminum Alloy - 2011 | | 23.0 |
| Aluminum Alloy - 2017 | | 23.6 |
| Aluminum Alloy - 2024 | | 23.2 |
| Aluminum Alloy - 3003 | | 23.2 |
| Aluminum Alloy - 5052 | | 23.8 |
| Aluminum Alloy - 5086 | | 23.8 |
| Aluminum Alloy - 6061 | | 23.4 |
| Aluminum Alloy - 7075 | | 23.6 |
| Antimony | | 9.0 |
| Beryllium | | 12.1 |
| Beryllium Copper | 20-100 | 16.7 |
| Bismuth | | 13.0 |
| Cast Iron, grey | 0-100 | 10.4 |
| Cast Steel, 3% C | | 12.6 |
| Chromium | | 5.9 |
| Cobalt | | 12.1 |
| Copper | 20-300 | 17.6 |
| Copper-Base Alloy - | | 21.2 |
| Manganese Bronze | | |
| Copper-Base Alloy - C1100 | | 17.6 |
| Copper-Base Alloy - C14500 | | 17.8 |
| Copper-Base Alloy - C17200, | | 17.8 |
| C17300 | | |
| Copper-Base Alloy - C18200 | | 17.6 |
| Copper-Base Alloy - C18700 | | 17.6 |
| Copper-Base Alloy - C22000 | | 18.4 |
| Copper-Base Alloy - C23000 | | 18.7 |
| Copper-Base Alloy - C26000 | | 20.0 |
| Copper-Base Alloy - C27000 | | 20.3 |
| Copper-Base Alloy - C28000 | | 20.9 |
| Copper-Base Alloy - C33000 | | 20.2 |
| Copper-Base Alloy - C35300 | | 20.3 |
| Copper-Base Alloy - C35600 | | 20.5 |
| Copper-Base Alloy - C36000 | | 20.5 |
| Copper-Base Alloy - C36500 | | 20.9 |
| Copper-Base Alloy - C46400 | | 21.2 |
| Copper-Base Alloy - C51000 | | 17.8 |
| Copper-Base Alloy - C54400 | | 17.3 |
| Copper-Base Alloy - C62300 | | 16.2 |
| Copper-Base Alloy - C62400 | | 16.6 |
| Copper-Base Alloy - C63000 | | 16.2 |
| Copper-Base Alloy - Nickel- | | 16.2 |
| Silver | | |
| Cupronickel | 20-300 | 16.2 |
| Ductile Iron, A536 (120-90- | | 10.6-11.2 |
| 02) | | |
| Gold | | 14.2 |
| Hastelloy C | 21-93 | 9.5 |
| Inconel | 20-100 | 11.5 |
| Incoloy | 0-100 | 14.4 |
| Iridium | | 5.9 |
| Iron, nodular pearlitic | 20-100 | 11.7 |
| Iron, pure | 20-100 | 12.2 |
| Magnesium | | 25.2 |
| Malleable Iron, A220 (50005, | | 13.5 |
| 60004, 80002) | | |
| Manganese | | 21.6 |
| Manganese Bronze | 20-300 | 21.2 |
| Molybdenum | | 5.4 |
| Monel | 0-100 | 14.0 |
| Nickel-Base Alloy - Nickel | | 15.3 |
| 200, 201, 205 | | |
| Nickel-Base Alloy - | | 12.4 |
| Hastelloy C-22 | | |
| Nickel-Base Alloy - | | 11.2 |
| Hastelloy C-276 | | |
| Nickel-Base Alloy - Inconel | | 13.0 |
| 718 | | |
| Nickel-Base Alloy - Monel | | 15.7 |
| Nickel-Base Alloy - Monel | | 13.9 |
| 400 | | |
| Nickel-Base Alloy - K500 | | 13.7 |
| Nickel-Base Alloy - R405 | | 13.7 |
| Nickel Wrought | 25-100 | 13.3 |
| Niobium (Columbium) | | 7.0 |
| Red Brass | 20-300 | 18.7 |
| Osmium | | 5.0 |
| Platinum | | 9.0 |
| Plutonium | | 35.7 |
| Potassium | | 82.8 |
| Rhodium | | 7.9 |
| Selenium | | 37.8 |
| Silicon | | 5.0 |
| Silver | | 19.8 |
| Sodium | | 70.2 |
| Stainless Steel - S30100 | | 16.9 |
| Stainless Steel - S30200, | | 17.3 |
| S30300, S30323 | | |
| Stainless Steel - S30215 | | 16.2 |
| Stainless Steel - S30400, | | 17.3 |
| S30500 | | |
| Stainless Steel - S30430 | | 17.3 |
| Stainless Steel - S30800 | | 17.3 |
| Stainless Steel - S30900, | | 14.9 |
| S30908 | | |
| Stainless Steel - S31000, | | 15.8 |
| S31008 | | |
| Stainless Steel - S31600, | | 15.8 |
| S31700 | | |
| Stainless Steel - S31703 | | 16.6 |
| Stainless Steel - S32100 | | 16.6 |
| Stainless Steel - S34700 | | 16.6 |
| Stainless Steel - S34800 | | 16.7 |
| Stainless Steel - S38400 | | 17.3 |
| Stainless Steel - S40300, | | 9.9 |
| S41000, S41600, 41623 | | |
| Stainless Steel - S40500 | | 10.8 |
| Stainless Steel - S41400 | | 10.4 |
| Stainless Steel - S42000, | | 10.3 |
| S42020 | | |
| Stainless Steel - S42200 | | 11.2 |
| Stainless Steel - S42900 | | 10.3 |
| Stainless Steel - S43000, | | 10.4 |
| S43020, S43023 | | |
| Stainless Steel - S43600 | | 9.4 |
| Stainless Steel - S44002, | | 10.3 |
| S44004 | | |
| Stainless Steel - S44003 | | 10.1 |
| Stainless Steel - S44600 | | 10.4 |
| Stainless Steel - S50100, | | 11.2 |
| S50200 | | |
| Tantalum | | 6.5 |
| Thorium | | 12.1 |
| Tin | 0-100 | 23.0 |
| Titanium | 20-93 | 8.6 |
| Titanium Alloy - Ti—5Al—2.5Sn | | 9.5 |
| Ti—8Mn | | 10.8 |
| Tungsten | | 4.5 |
| Uranium | | 13.3 |
| Vanadium | | 7.9 |
| Wrought Carbon Steel | 21-427 | 14.0 |
| Yellow Brass | 20-300 | 20.3 |
| Zinc | | 34.2 |

The smaller the difference between the CTE of a target-facing surface and the CTE of a coating material (i.e., Δ CTE) the lower the occurrence and/or frequency of fracturing and flaking of a coated material because thermal cycling within a sputtering chamber will have a smaller effect on the structural integrity of the coating material. When a coating material and a substrate support are thermally cycled, the coating material and support will expand and contract at different rates due to the Δ CTE of the coating material and support. The different rates of expansion and contraction may eventually result in the coating material fracturing and flaking off the substrate support due to stresses created by the different rates/amounts of thermal expansion for the coating material and the substrate support. The more times a coating material and a substrate support are thermally cycled, the higher the probability that a coating material will begin to fracture.

Typically, to avoid fracturing and flaking of a coating material, at least the target-facing surfaces of a substrate support are periodically cleaned to remove deposited coating material. In some cases, at least the target-facing surfaces of a substrate support may be cleaned by etching these surfaces with a strong acid and/or base (e.g., NaOH) to remove coating material deposited on these surfaces. In such cases, the etching may be performed at a temperature in the range of 50 degrees C. to 90 degrees C. In some cases, at least the target-facing surfaces of a substrate support may be cleaned by thermally shocking the target-facing surfaces to intentionally fracture and remove coating material deposited on these surfaces. While beneficial to re-use substrates supports, such cleaning processes may be expensive and time consuming. And, this cleaning may damage the substrate support over time.

It has been observed that aluminum substrate supports are susceptible to deterioration during chemical stripping of a coating material (e.g., cleaning with a strong acid or base) and a protective coating of Teflon may be applied to the aluminum to help protect the aluminum from deterioration. However, it has been observed by the inventors that stainless steel or titanium alloy substrate supports have a higher resistance to deterioration during chemical stripping of a coating material, compared to aluminum substrate supports.

An aluminum substrate support coated with a protective layer of Teflon typically lasts through about 20 cleanings with a strong acid or base before it becomes unusable due to damage from the cleanings. And, a Teflon-coated aluminum substrate support must be cleaned after 1 to 2 sputter deposition processes to avoid fracturing and flaking of coated material(s). In contrast, it has been observed by the inventors that a stainless steel or titanium alloy can withstand 20 strong acid or base cleanings before it becomes unusable. And a stainless steel or titanium alloy only needs to be cleaned after about 10 deposition processes to avoid fracturing and flaking of coated material(s).

Coating delamination may be due to intrinsic stress (proportional to coating thickness and process) and extrinsic stress (CTE mismatching with substrates or adjacent layers). Eliminating the need for a Teflon coating reduces cost and simultaneously increases the number of times a substrate support can be used before cleaning is required. It has been observed by the inventors that a stainless steel substrate support fixture can be coated with a layer of coating material having a thickness up to about twenty microns (um) before the coating material begins to fracture and flake off the substrate support. In contrast, it has been observed that a Teflon coated substrate support can only be coated with a maximum eight microns of a coating material before the material begins to fracture and flake. It is believed this is due to the superior inherent bonding strength between the coating material and a metal, e.g., stainless steel, compared to the inherent bonding strength between the coating material and Teflon.

Further, a smaller Δ CTE may reduce the frequency of the cleanings for a substrate support. This reduction in frequency is a result of the coated material being less likely to fracture due a smaller Δ CTE. In some embodiments, the CTE of a non-aluminous and non-magnetic metallic material may be 21.6 ppm/° C. or less at 20° C. In some embodiments, the CTE of a non-aluminous and non-magnetic material may be 18 ppm/° C. or less at 20° C. In some embodiments, the CTE of a non-aluminous material and non-magnetic metallic material may be 16.2 ppm/° C. or less at 20° C. These CTE values are relatively low compared to that of aluminum substrate supports typically used. The lower CTE results in a substrate support that can be used more times before flaking occurs. For example, a substrate support made of 316 stainless steel may be used for up to 10 sputtering deposition processes before cleaning to avoid flaking.

Cleaning with reduced frequency has several advantages. First, the cleaning process itself is time consuming and expensive. Reduced cleaning frequency reduces this cost. Second, cleaning damages the substrate support. 20 strong acid or base cleanings of a 316 stainless steel substrate support, with 10 deposition processes per cleaning, will result in 200 uses of the substrate support. By way of contrast, 20 strong acid or base cleanings of an aluminum substrate support at 1 to 2 deposition processes per cleaning will result in 10-20 uses of the support substrate. This difference results in considerable cost savings due to replacing the substrate support less frequently due to cleaning damage.

In some embodiments, a substrate support may include no adhesive to eliminate the possibility of adhesive outgassing within a sputtering chamber. In some embodiments, a substrate support may employ a limited amount of adhesive material to limit the amount of possible adhesive outgassing within a sputtering chamber. Substrate supports that minimize, or completely eliminate, the use of adhesives, like double sided Kapton® tape, eliminate or reduce undesirable chemical reactions between adhesive outgasses and a coating material being deposited. Accordingly, the formation of coating defects, for example un-removable stains on the substrates, is reduced or eliminated. Additionally, eliminating or limiting the amount of adhesive may reduce the time and cost of a sputtering process. The application of an adhesive can be time consuming and may disadvantageously require re-application between sputtering runs. Constant re-application of the adhesive may be expensive, particularly if the cost of the adhesive is be high.

In some embodiments, a substrate support may include two plates to secure at least one substrate to the substrate support by clamping the substrate between the two plates. In some embodiments, the two plates may secure one or more substrates to the substrate support without adhesive. Clamping the substrate(s) between two plates may eliminate the use of any adhesive on a substrate support and may inhibit the possibility of substrates falling from the substrate support. In some embodiments, the two plates may include a top plate and a bottom plate, the top plate including one or more apertures for allowing all or a portion of a substrate positioned below a respective aperture to be coated with a coating material.

In some embodiments, a substrate support may include a vacuum plate with a plurality of through holes. The vacuum plate may be used to pull a substrate towards an adhesive on a top surface of the vacuum plate. Pulling the substrate towards the adhesive with a vacuum may create a strong adhesive bond between a substrate and adhesive on the vacuum plate, thereby limiting the amount of adhesive to secure the substrate to a substrate support, and inhibiting the possibility of substrates falling from the substrate support. Moreover, the use of a vacuum plate may limit the amount of human interaction (e.g., touching) of substrates to secure them to a substrate support. A vacuum applied to the vacuum plate may serve to bond substrates to an adhesive on the vacuum plate without manual human force (e.g., manually pushing substrates into contact with an adhesive). Still furthermore, the use of a vacuum may create a more consistent bond between substrates and an adhesive because vacuum pressure can be applied uniformly to all substrates on the vacuum plate, rather than relying on consistent and uniform manual pressing of substrates to an adhesive.

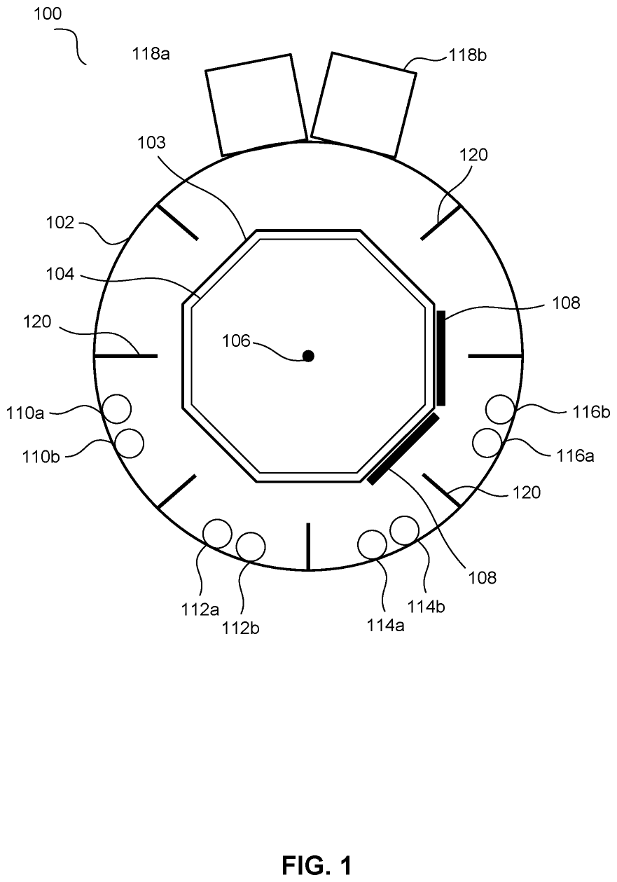

FIG. 1 illustrates a top-down view of an example sputtering device 100 for sputtering a material onto a plurality of substrates. In some embodiments, sputtering device 100 may be a drum sputtering device. Sputtering device 100 includes a chamber 102 within which sputtering of a coating material occurs. The pressure within chamber 102 during a sputter process may be from 1 mTorr to 10 mTorr. Although chamber 102 is illustrated as being circular, this is not required and any shape of chamber 102 may be used. In some embodiments, sputtering device 100 may be a magnetron sputtering device.

Within chamber 102 is a rotating drum 103 including a frame 104, according to some embodiments. Frame 104 may be composed of a metallic material, including but not limited to, aluminum, stainless steel, or titanium. Frame 104 may be designed to rotate about an axis 106. In some embodiments, frame 104 may rotate at a speed from 5 to 10 meters per second. In some embodiments, frame 104 may rotate at a speed from 0 to 100 RPM. In some embodiments, frame 104 may be characterized by having a polyhedron shape, where each face of the polyhedron is configured to couple with a substrate support 108. In some embodiments, frame 104 may include one or more fasteners, such as screws, clamps, or brackets, for coupling substrate support(s) 108 to frame 104. In the example illustrated in FIG. 1, frame 104 has an octagonal shape. However, frame 104 may have any number of faces where each face is capable of coupling with a substrate support 108. In some examples, frame 104 may have anywhere from 7 to 91 faces.

Substrate supports 108 are designed to hold one or more fixtures (e.g., fixtures 202, 300, or 600 described herein) and the fixtures may hold one or more substrates (e.g., substrates 204, 350, or 630 described herein). In this way, many substrates may be arranged within chamber 102 to have various thin material films deposited upon them.

The rotation of frame 104 causes the substrates to be subjected to various portions of chamber 102 during a sputter deposition process. Different portions of chamber 102 may include different sputtering targets and/or different reactive gases. For example, some portions of chamber 102 may be defined by having pairs of sputtering targets such as 110a and 110b, 112a and 112b, 114a and 114b, and 116a and 116b. Each pair of sputtering targets includes a pure or nearly pure form of a material to be deposited onto the surface of the substrates. Some common sputtering targets include, but are not limited to, silicon (Si), aluminum (Al), tantalum (Ta), zirconium (Zr), niobium (Nb), gold (Au), titanium (Ti), and chromium (Cr). The targets may be arranged in pairs so that a positive voltage is applied to one sputtering target (e.g., target 110a) while a negative voltage is applied to the other corresponding sputtering target (e.g., target 110b). An inert gas such as argon or xenon may be used in chamber 102 around the various sputtering targets 110a, 110b, 112a, 112b, 114a, 114b, 116a, and 116b. Although only four pairs of sputtering targets are illustrated, any number of sputtering targets may be employed within chamber 102. In some embodiments, each sputtering target pair may be separated from the others using walls 120. Although paired sputtering targets that eject material based on applied voltage between the targets are illustrated, any suitable sputtering arrangement may be used.

In some embodiments, a portion of chamber 102 may include inductively coupled plasma sources 118a and 118b to generate a plasma using reactive gases such as oxygen and nitrogen. This reactive region can cause metal films deposited from any of the sputtering targets to be oxidized or nitrified. For example, an aluminum film may become aluminum oxide (Al₂O₃) or aluminum nitride (AlN).

Substrate supports 108 may be removably coupled to a given face of frame 104 using a variety of techniques. In some embodiments, one or more substrate supports 108 may hook onto portions of frame 104 for easy loading and unloading of substrate support(s) 108. In some embodiments, one or more substrate supports 108 may be clamped onto portions of frame 104 using clamps.

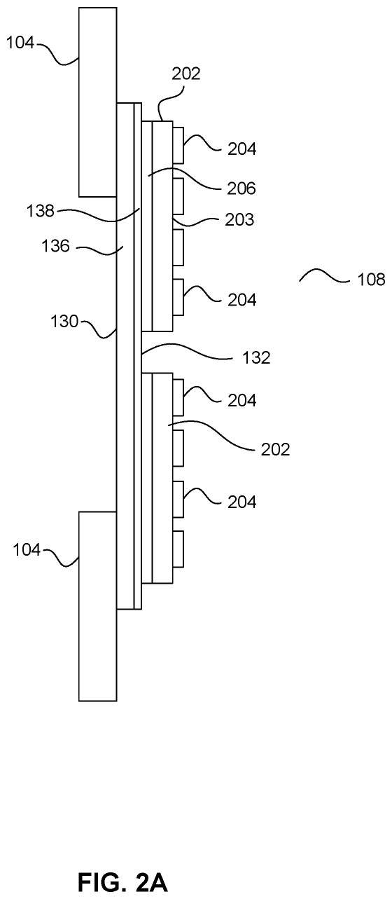

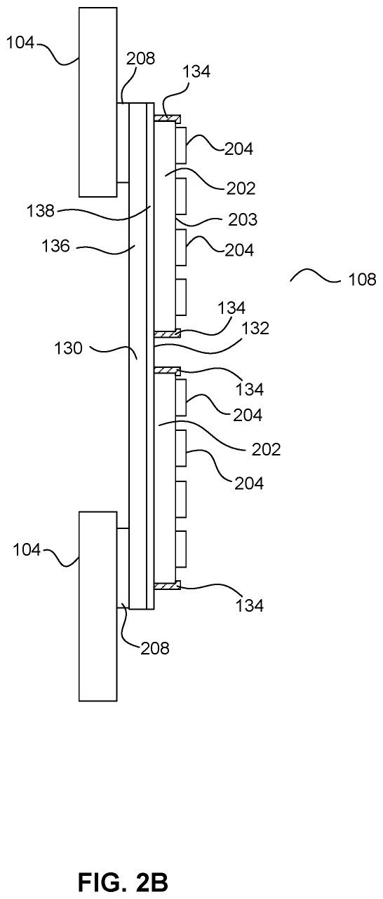

FIG. 2A illustrates a substrate support 108 according to some embodiments. Substrate support 108 may include a carrier 130 and one or more fixtures 202. Fixture(s) 202 may be coupled to carrier 130 and may hold one or more substrates 204. Substrates 204 may be glass articles, such as cover glasses, or may be semiconductor wafers, such as silicon, indium phosphide, or gallium arsenide. In some embodiments, fixture(s) 202 may include a plurality of segments, and each segment may hold a substrate from the one or more substrates. Fixtures 202 may be the same as or similar to fixture 300 or fixture 600 discussed herein. In some embodiments, a fixture(s) 202 may hold anywhere from one to thirty substrates 204.

In some embodiments, substrates 204 may be cover glasses for a consumer electronic product, for example a mobile phone or wearable device (e.g., a watch). In such embodiments, substrates 204 may be 2D, 2.5D, or 3D cover glasses.

In some embodiments, carrier 130 may be removably coupled to frame 104. In some embodiments, carrier 130 may hook on a portion of frame 104 for easy loading and unloading of carriers 130. In another example, carrier 130 may be clamped onto portions of frame 104 using clamps.

In some embodiments, an adhesive 206 may be used to couple fixture(s) 202 to carrier 130. Adhesive 206 may be, but is not limited to, a double-sided tape, such as Kapton® tape. In some embodiments, the presence of adhesive 206 may reduce arcing at the surface of carrier 130 (by protecting the surface from the plasma energy).

FIG. 2B illustrates a substrate support 108 according to some embodiments. As discussed above in FIG. 2A, substrate support 108 may include one or more fixtures 202, and at least one or all fixtures 202 may hold one or more substrates 204. In some embodiments, an insulative material 208 may be disposed at each location where frame 104 is coupled to substrate support 108. Insulative material 208 may serve to electrically isolate substrate support 108 from frame 104, such that substrate support 108 has a floating electrical potential. In some embodiments, insulative material 208 may be a ceramic material or a plastic material that maintains its physical and chemical properties up to a temperature of 300 degrees C. In some embodiments, insulative material 208 may include a thick (at least one micrometer thick) metal oxide or metal nitride. It should be noted that a native oxide on either or both metal surfaces of frame 104 and substrate support 108 is not thick enough to act as an insulative material because it would not electrically isolate substrate support 108 from frame 104.

In some embodiments, insulative material 208 may have a thickness from 0.5 mm to 5 mm. In some embodiments, insulative material 208 may have a thickness around 1 mm. Insulative material 208 may block the deposition of coating material between frame 104 and substrate support 108. In some embodiments, insulative material 208 may be a coating around frame 104, substrate support 108, or both. In some embodiments, the coating may only be present at locations where frame 104 couples with substrate support 108. In some embodiments, insulative material 208 may be an integral part of frame 104, substrate support 108, or both.

As shown in both FIGS. 2A and 2B, fixtures 202 are coupled to a target-facing surface 132 of carrier 130. In some embodiments, at least target-facing surface 132 of carrier 130 may be composed essentially of (i.e., consists essentially of) one or more non-aluminous and non-magnetic metallic materials. As discussed above, a non-aluminous and non-magnetic metallic material reduces, or eliminates, undesirable physical interactions between a coating material and carrier 130 and helps prevent undesirable fracturing and flaking of the coating material. In some embodiments, at least target-facing surface 132 of carrier 130 may be composed entirely of (i.e., consists of) one or more non-aluminous and non-magnetic metallic materials. In some embodiments, the entire carrier 130 may be composed essentially of (i.e., consists essentially of) one or more non-aluminous and non-magnetic metallic materials.

In some embodiments, carrier 130 may include a plate 136 defining target-facing surface 132 of carrier 130. In some embodiments, plate 136 may consist essentially of (or consist of) one or more non-aluminous and non-magnetic metallic materials. In some embodiments, plate 136 may be a hollow plate. Reducing the mass of carrier 130 may reduce the carrier's ability to cause undesirable physical interactions between a coating material and carrier 130 (e.g., may reduce the magnitude of magnetic field created by carrier 130). In some embodiments, carrier 130 may weigh 100 kilograms or less.

In some embodiments, plate 136 may include a surface plate 138 defining target-facing surface 132 of carrier 130. In some embodiments, surface plate 138 may consist essentially of (or consist of) one or more non-aluminous and non-magnetic metallic materials. Surface plate 138 may prevent the remainder of carrier 130 (e.g., plate 136) from causing undesirable physical interactions between a coating material and carrier 130 while reducing the amount of non-magnetic and non-aluminous material for carrier 130.

In some embodiments, at least target-facing surface 132 of carrier 130 may consist essentially of (or consist of) stainless steel 316. In some embodiments, the entire carrier 130 may consist essentially of (or consist of) stainless steel 316. In some embodiments, plate 136 and/or surface plate 138 may consist essentially of (or consist of) stainless steel 316 heat treated at a temperature in the range of 600 degrees C. to 1400 degrees C. to remove magnetic charge from plate 136 and/or surface plate 138. In some embodiments, at least target facing surface 132 of carrier may consist essentially of (or consist of) stainless steel 316 heat treated at a temperature in the range of 600 degrees C. to 1400 degrees C. In some embodiments, the entire carrier 130 may consist essentially of (or consist of) stainless steel 316 heat treated at a temperature in the range of 600 degrees C. to 1400 degrees.

As shown in FIG. 2B, in some embodiments, carrier 130 may include one or more clamps 134 coupled to carrier 130. In some embodiments, clamps 134 may be coupled to target-facing surface 132 of carrier 130. Clamps 134 may couple fixture(s) 202 to target-facing surface 132 of carrier 130. Clamps 134 may be, but are not limited to, vice-type clamps, spring loaded clamps, or clamps secured with mechanical fasteners, such as screws. In some embodiments, to facilitate a quick removal of fixture(s) 202 from carrier 130, clamps 134 may not include screws. In some embodiments, clamps 134 may consist essentially of (or consist of) one or more non-aluminous and non-magnetic metallic materials.

In some embodiments, at least 90 volume percent of substrate support 108 may consist essentially of (or consist of) one or more non-aluminous and non-magnetic metallic materials. In some embodiments, at least 75 volume percent of substrate support 108 may consist essentially of (or consist of) one or more non-aluminous and non-magnetic metallic materials. In some embodiments, at least 50 volume percent of substrate support 108 may consist essentially of (or consist of) one or more non-aluminous and non-magnetic metallic materials.

In some embodiments, all the target-facing surfaces (e.g., surfaces 203 and 132) of substrate support 108 may consist essentially of (or consist of) one or more non-aluminous and non-magnetic metallic materials. In some embodiments, the entire substrate support 108 may consist essentially of (or consist of) one or more non-aluminous and non-magnetic metallic materials.

In some embodiments, fixture(s) 202 may consist essentially of (or consist of) one or more non-aluminous and non-magnetic metallic materials. In some embodiments, at least a target-facing surface 203 of fixture(s) 202 may consist essentially of (or consist of) one or more non-aluminous and non-magnetic metallic materials.

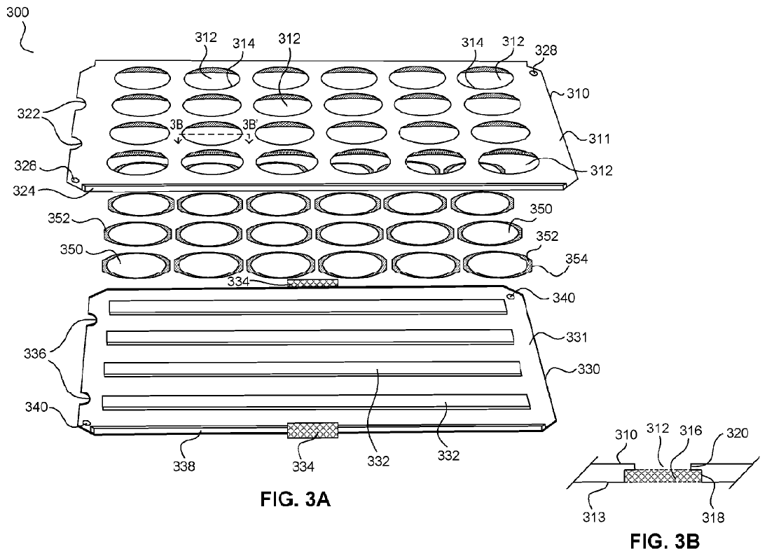

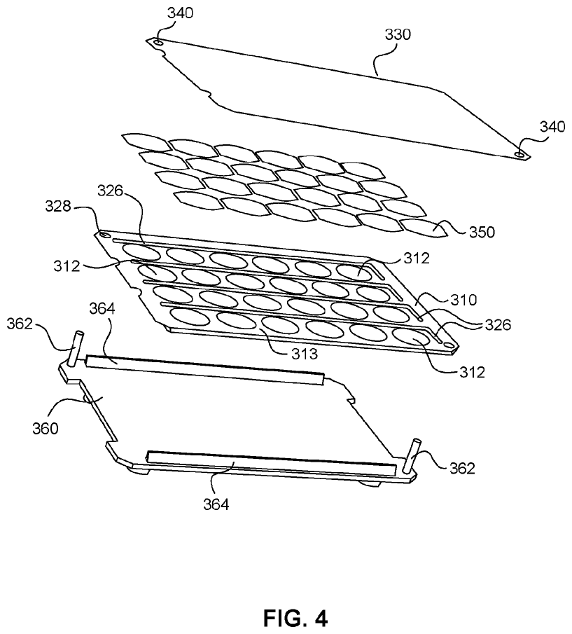

FIGS. 3A-4 illustrate a fixture 300 for holding substrates 350 according to some embodiments. Fixture 300 may include a bottom plate 330 including one or more an elastic pads 332 coupled to a top surface 331 of bottom plate 330. In operation, elastic pads 332 may be in direct contact with substrates 350 in contact with bottom plate 330 to frictionally secure substrates 350 to bottom plate 330 in desired locations. In some embodiments, elastic pads 332 may be composed, in whole or in part, of polytetrafluoroethylene (Teflon).

Fixture 300 also includes a top plate 310. In operation, top plate 310 may be coupled to bottom plate 330 with one or more clamps 334. Top plate 310 includes one or more apertures 312 for allowing at least a portion of a target-facing surface of substrate(s) 350 disposed below respective apertures 312 to be coated during a sputtering deposition process. In other words, apertures 312 may be disposed over at least a portion of respective substrates 350. In some embodiments, top plate 310 may include cavities 316 disposed below respective apertures 312. Cavities 316 may include a cavity sidewall 318 and a lip 320 extending from cavity sidewall 318 and defining a perimeter 314 of a respective aperture 312.

In some embodiments, top surface (target facing surface) 311 of top plate 310 may consist essentially of (or consist of) one or more non-aluminous and non-magnetic metallic materials. In some embodiments, entire top plate 310 may consist essentially of (or consist of) one or more non-aluminous and non-magnetic metallic materials. In some embodiments, bottom plate 330, with the exception of pads 332, may consist essential essentially of (or consist of) one or more non-aluminous and non-magnetic metallic materials.

Clamps 334 may secure top plate 310 to bottom plate 330 and, in operation, clamp substrates 350 between bottom plate 330 and top plate 310. In some embodiments, fixture 300 may include two clamps 334 disposed on opposing sides of fixture 300. In some embodiments, clamps 334 may be an integral part (e.g., integrally formed with, welded to, or permanently fixed to) either top plate 310 or bottom plate 330. Clamps 334 may be but are not limited to, vice-type clamps, spring loaded clamps, or clamps secured with mechanical fasteners, such as screws. In some embodiments, to facilitate quick coupling and de-coupling of top plate 310 and bottom plate 330, clamps 334 may not include screws. In some embodiments, clamps 334 may consist essentially of (or consist of) one or more non-aluminous and non-magnetic metallic materials.

Cavities 316 may be configured (e.g., sized and shaped) to receive all or a portion of a substrate 350. In some embodiments, a portion of cavity sidewall 318 may include a surface profile that corresponds to the shape of a portion of a perimeter edge 354 of a substrate 350. In some embodiments, the size and shape of a cavity sidewall 318 may correspond to the size and shape of a perimeter edge 354 of a substrate 350. In some embodiments, the size and shape of a cavity sidewall 318 may be different than the size and shape of a perimeter edge 354 of a substrate 350. Lip 320 may be disposed over a peripheral portion (e.g., flange) 352 of a substrate 350. Lip 320 may cover peripheral portion 352 and prevent coating material from be deposited on peripheral portion 352 during a sputtering deposition process. In such embodiments, fixture 300 may be used for non-edge-to-edge coating of substrates 350.

In some embodiments, as shown for example in FIG. 4, top plate 310 may include a plurality of alignment tracks 326 disposed on a bottom surface 313 of top plate 310. Alignment tracks 326 may be areas of increased thickness relative to bottom surface 313 of top plate 310. In other words, alignment tracks 326 may protrude from bottom surface 313. In such embodiments, alignment tracks 326 may help align substrates 350 relative to apertures 312 of top plate 310. In some embodiments, alignment tracks 326 may replace cavities 316 on top plate 310.

In some embodiments, top plate 310 may be tailored for a specific glass article (e.g., a specific cover glass) and bottom plate 330 may be used for a number of different kinds of glass articles (e.g., different cover glasses). In such embodiments, apertures 312 may be sized and shaped for a specific glass article. Such customization may facilitate an easy transition between sputter coating processes for different kinds of glass articles.

In some embodiments, bottom plate 330 and/or top plate 310 may include one or more alignment features to aid in properly aligning bottom plate 330, top plate 310, and substrates 350 relative to each other for a sputtering deposition process. In some embodiments, bottom plate 330 may include at least one alignment detent 336 and top plate 310 may include at least one alignment detent 322 to align with a corresponding alignment detent 336 on bottom plate 330. In some embodiments, bottom plate 330 may include at least one alignment groove 338 and top plate 310 may include at least one alignment groove 324 to engage alignment groove 338. In some embodiments, bottom plate 330 may include at least one alignment hole 340 and top plate 310 may include at least one alignment hole 328 to align with a corresponding alignment hole 340 on bottom plate 330.

In some embodiments, an alignment plate 360 (see FIG. 4) may be used to align top plate 310 and bottom plate 330. In some embodiments, alignment plate 360 may include at least one alignment post 362 to be received by alignment holes 328 and 340 in top plate 310 and bottom plate 330, respectively. In some embodiments, alignment plate 360 may include at least one alignment rail 364 to be received by alignment groove 324 of top plate 310 and/or alignment groove 338 of bottom plate 330.

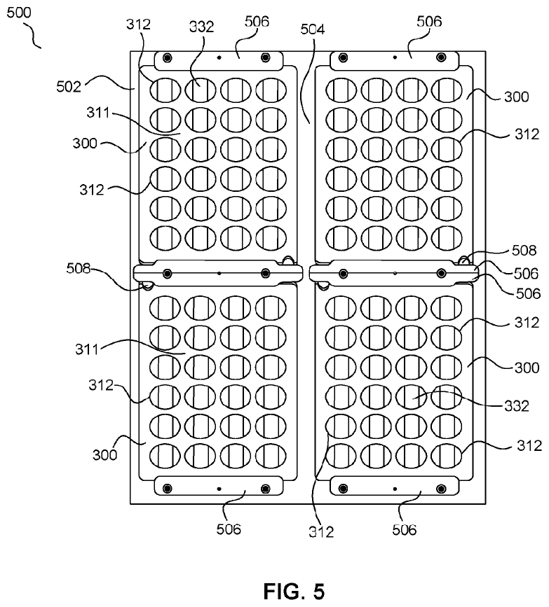

As shown, for example in FIG. 5, in some embodiments, a substrate support may hold a plurality of fixtures with at least one fixture holding one or more substrates. Substrate support 500 may include a carrier 502 and a plurality of fixtures 300 coupled to a target-facing surface 504 of carrier 502. Carrier 502 may be the same as or similar to carrier 130 discussed herein.

As shown in FIG. 5, carrier 502 may include a plurality of clamps 506 to couple (i.e., clamp) fixtures 300 to carrier 502. Clamps 506 may be the same as or similar to clamps 134 discussed above in connection with carrier 130. In some embodiments, clamps 506 may include one or more alignment protrusions 508 for aligning fixtures 300 on carrier 502. In such embodiments, alignment protrusions 508 may engage alignment detents 322 and/or alignment detents 336 on top plate 310 and bottom plate 330 of fixture 300, respectively. In some embodiments, alignment protrusions 508 may be alignment detents and alignment detents 332/336 may be alignment protrusions. While carrier 502 is shown in FIG. 5 holding fixtures 300, carrier 502 may also hold fixtures 600.

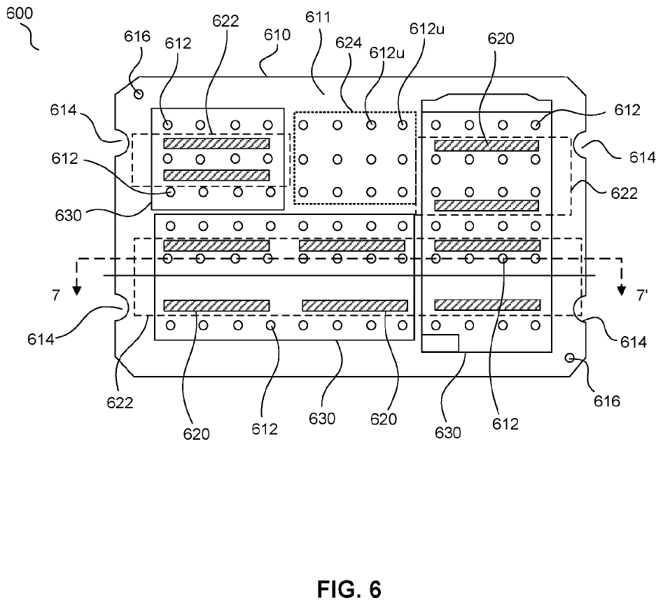

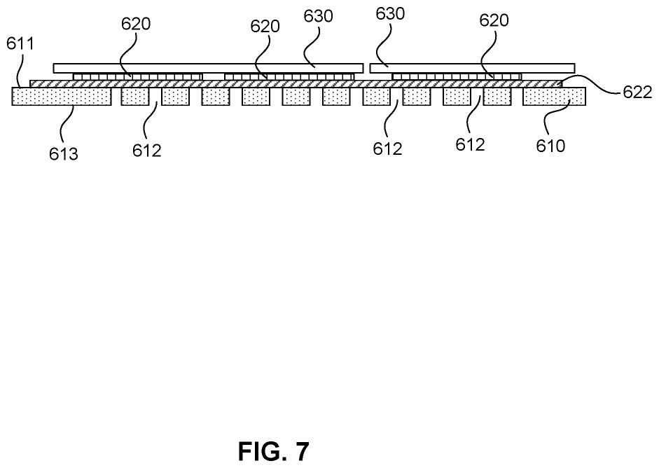

FIGS. 6 and 7 illustrate a fixture 600 for holding substrates 630 according to some embodiments. Fixture 600 may include one or more double sided adhesive layer(s) 620 to secure substrate(s) 630 to a vacuum plate 610. The use of double sided adhesive layer(s) 620 may facilitate edge-to-edge coating of substrates 630 during a sputtering deposition process. Double sided adhesive layer(s) 620 may secure substrates 630 to vacuum plate 610 without covering a peripheral edge of substrates 630.

Vacuum plate 610 of fixture 600 includes a plurality of through holes 612 extending from a top surface (target-facing surface) 611 to a bottom surface 613 of vacuum plate 610. In some embodiments, through holes 612 may have a diameter in the range of 0.5 mm to 3.0 mm. In some embodiments, through holes 612 may be arranged in a plurality of rows extending across the length of vacuum plate 610. Through holes 612 may be arranged in any desired pattern, and in some embodiments, may be arranged in a patterned tailored for a specific kind of glass article (e.g., a specific kind of cover glass).

In some embodiments, top surface 611 of vacuum plate 610 may consist essentially of (or consist of) one or more non-aluminous and non-magnetic metallic materials. In some embodiments, entire vacuum plate 610 may consist essentially of (or consist of) one or more non-aluminous and non-magnetic metallic materials.

Double sided adhesive layer(s) 620 may be disposed over a portion of top surface (target-facing surface) 611 of vacuum plate 610. In some embodiments, double sided adhesive layer(s) 620 may be in direct contact with a portion of top surface 611 of vacuum plate 610. In operation, double-sided adhesive layer(s) 620 adhesively couple substrate(s) 630 to vacuum plate 610. In some embodiments, double sided adhesive layers 620 may cover at least one through hole 612 in vacuum plate 610. In operation, a substrate 630 may be disposed on top surface 611 over one or more double sided adhesive layers 620 and over at least one through hole 612 in vacuum plate 610.

In some embodiments, fixture 600 may include one or more adhesive layers 622 disposed between double sided adhesive layer(s) 620 and vacuum plate 610. In some embodiments, adhesive layer(s) 622 may be in directed contact with top surface 611 of vacuum plate 610. Adhesive layer(s) 622 may cover at least one through hole 612 in vacuum plate 610. Adhesive layer(s) 622 may facilitate the removal of substrates 630 from vacuum plate 610 after substrates 630 are adhesively bound to double sided adhesive layer(s) 620 with vacuum pressure. In operation, a substrate 630 may be disposed over at least a portion of one or more adhesive layers 622 and at least one through hole 612 that is not covered by adhesive layer(s) 622. In some embodiments, adhesive layer(s) 622 may be a single side adhesive (e.g., single sided adhesive tape) adhered to top surface 611 of vacuum plate 610. In such embodiments, the adhesive side of the single sided adhesive tape may face way from double side adhesive layer(s) 620 disposed over adhesive layer(s) 622.

In some embodiments, fixture 600 may include one or more airtight sealant layers 624 covering any through holes 612 in vacuum plate 610 not covered by a substrate 630, a double sided adhesive layer 620, or an adhesive layer 622 (i.e., through holes 612u). Airtight sealant layers 624 may include, but are not limited to an adhesive tape layer or an elastic gasket. Covering any uncovered through holes 612u will ensure adequate vacuum pressure is applied by a vacuum box to adhesively bond substrates 630 to double sided adhesive layer(s) 620 (see e.g., method 1000 and/or method 1100).

In some embodiments, top plate 310 of fixture 300 may be used in combination with vacuum plate 610 to secure substrates 630 to vacuum plate 600. In such embodiments, vacuum plate 600 may take the place of bottom plate 330 discussed above in regards to fixture 300. In some embodiments, vacuum plate 610 may include one or more alignment detents 614 to align with a corresponding alignment detent 322 on top plate 310. In some embodiments, vacuum plate 610 may include one or more alignment holes 616 to align with a corresponding alignment hole 328 on top plate 310.

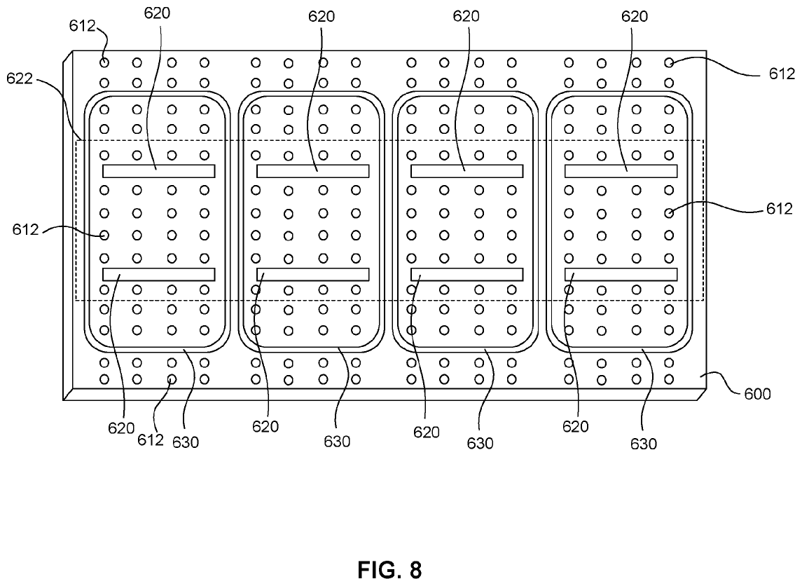

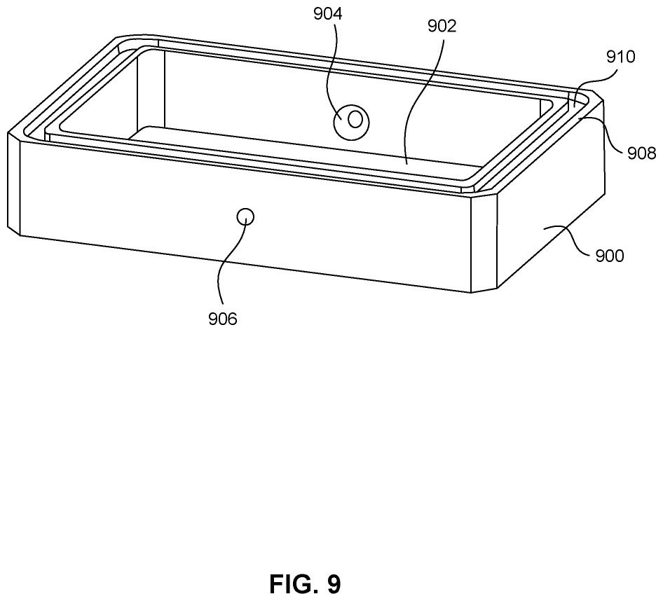

FIG. 8 shows a plurality of substrates 630 secured to vacuum plate 610 with a plurality of double sided adhesive layers 620 according to some embodiments. Substrates 630 may be adhesively bounded to double sided adhesive layers 620 using a vacuum box. FIG. 9 shows a vacuum box 900 according to some embodiments. Vacuum box 900 may include a vacuum cavity 902 and a sealing surface 908 over which vacuum plate 610 is placed. In some embodiments, sealing surface 908 may include a gasket groove 910 for receiving an elastic gasket to facilitate the formation of an airtight seal between bottom surface 613 of vacuum plate 610 and sealing surface 908.

Vacuum box 900 may also include a vacuum port 904 for coupling with a vacuum source (e.g., a vacuum hose of a vacuum pump). Vacuum port 904 allows the vacuum source to reduce the pressure within vacuum cavity 902 when vacuum plate 610 is sealed to sealing surface 908. In some embodiments, vacuum box 900 may include a release valve 906 for releasing the vacuum within vacuum cavity 902 after substrates 630 are adhesively bonded to double sided adhesive layers 620 via the pulling force created by reducing the pressure in vacuum cavity 902.

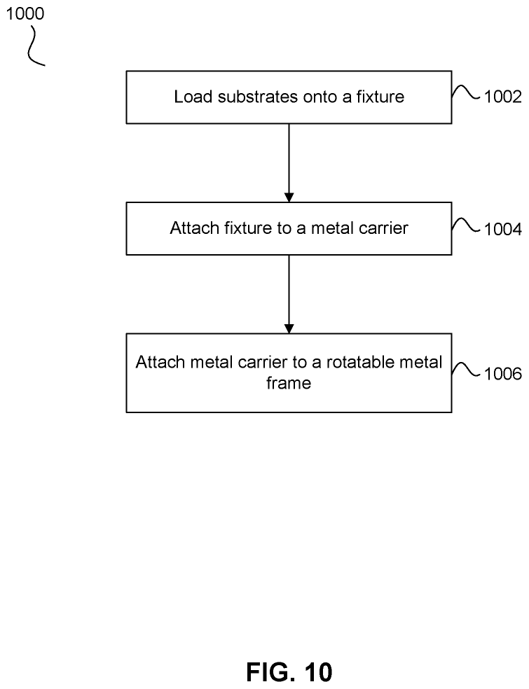

FIG. 10 illustrates a method 1000 of loading substrates into a sputtering device (e.g., sputtering device 100) according to some embodiments. While FIG. 10 shows various steps of method 1000 performed in an order, the steps may be performed in a different order. Additionally, the steps need not be performed at the same location or same time. The steps may be performed at different locations or at different times.

Method 1000 begins at step 1002 where one or more substrates (e.g., substrates 204, 350, or 630) are coupled to a fixture (e.g., fixture 202, fixture 300, or fixture 600). In some embodiments, substrates may be coupled to a fixture (e.g., fixture 300) by clamping the substrates to the fixture. In such an embodiment, substrate(s) may be secured to fixture 300 by disposing top plate 310 on alignment plate 360. Then, one or more substrates may be disposed on top plate 310 (e.g., in cavities 316 of top plate 310) and bottom plate 330 may be disposed over top plate 310 and the substrate(s) such that elastic pad(s) 332 on bottom plate 330 contact(s) the substrate(s). And then, top plate 310 and bottom plate 330 may be removed from alignment plate 360, with the substrates disposed between top plate 310 and bottom plate 330. In some embodiments, top plate 310 and bottom plate 330 may be clamped together with clamps (e.g., clamps 334) coupled to top plate 310 and/or bottom plate 330.

In some embodiments, substrates may be coupled to a fixture (e.g., fixture 600) by adhesively bonding the substrates to the fixture. In such an embodiment, vacuum pressure may be employed to adhesively bond the substrates to an adhesive disposed on top surface 611 of fixture 600. In some embodiments, substrates may be secured to fixture 600 by disposing substrates on vacuum plate 610 having one or more double sided adhesive layers 620 disposed over a portion of top surface (target-facing surface) 611 of vacuum plate 610. When disposing substrate(s) on vacuum plate 610, the substrate(s) are disposed on top surface 611 of the vacuum plate 610 over one or more double sided adhesive layers 620 and over at least one through hole 612 in vacuum plate 610 not covered by an adhesive or sealant. After disposing the substrate(s) on vacuum plate 610, vacuum plate may be placed on a vacuum box (e.g., vacuum box 900) and a vacuum may be applied to vacuum box 900 to pull the substrate(s) towards vacuum plate 610 to bond the substrate(s) to double sided adhesive layer(s) 620. The vacuum pulled through the though hole(s) 612 over which the substrate(s) are disposed serves to pull the substrate(s) toward vacuum plate 610, and thus bond them to double sided adhesive layer(s) 620.

In some embodiments, any through holes 612 that are not covered by the double sided adhesive layer(s) 620 and the substrate(s) (e.g., uncovered through holes 612u) may be covered with airtight sealant 624 (e.g., an adhesive or an elastic gasket) before applying vacuum to vacuum box 900. In some embodiments, adhesive layer(s) 622 may be disposed between double sided adhesive layer(s) 620 and the substrate(s), and cover at least one through hole 612 in vacuum plate 610.

After the substrate(s) is/are secured to a fixture in step 1002, fixture(s) may be coupled to a carrier (e.g., carrier 130) in step 1004. In some embodiments, the carrier may hold a plurality of fixtures (see e.g., FIG. 5). For example, in some embodiments, a carrier may hold from two to six fixtures. In some embodiments, the fixture(s) may be coupled to the carrier by hooking the fixture(s) on the carrier. In some embodiments, the fixture(s) may be coupled to the carrier with one or more clamps (see e.g., FIG. 5).

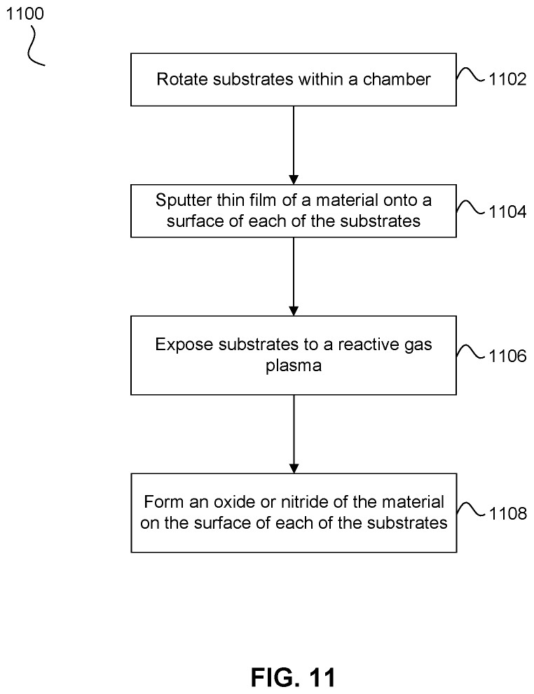

Once the fixture(s) are coupled to a carrier, the carrier may be coupled to a rotatable frame (e.g., frame 104) of a sputtering device (e.g., sputtering device 100). In some embodiments, the carrier may be coupled to the frame by hooking the carrier on the frame with flanges coupled to (e.g., integrally formed with or mechanically fastened to) the carrier. In some embodiments, the flanges may be composed, in whole or in part, of an insulative material. In some embodiments, the carrier may be coupled to the frame with one or more clamps. After step 1004, the substrate(s) may be sputter coated, for example using the sputtering deposition method 1100 illustrated in FIG. 11.

FIG. 11 illustrates a method 1100 of performing a sputter deposition process according to some embodiments. While FIG. 11 shows various steps of method 1100 performed in an order, the steps may be performed in a different order. Additionally, the steps need not be performed at the same location or same time. The steps may be performed at different locations or at different times. The various operations of method 1100 may be performed using a sputtering device, such as sputtering device 100. In some embodiments, method 1100 may be a drum sputtering method. In some embodiments, method 110 may be a magnetron sputtering method.

Method 1100 begins at step 1102 when one or more substrates are rotated within a sputtering chamber (e.g., chamber 102). The substrate(s) may be coupled to fixtures and carriers, which in turn are coupled to a rotating drum frame (see method 1000). In some embodiments, the frame may rotate the substrates at a speed from 0 to 100 RPM.

After the substrate(s) begin to rotate, a thin film of a material is sputtered (coated) on a target-facing surface of the substrate(s) in step 1104. The sputtered material (i.e., coated material) may include a metallic material, such as but not limited to limited to silicon (Si), aluminum (Al), tantalum (Ta), zirconium (Zr), niobium (Nb), gold (Au), titanium (Ti), and chromium (Cr).

In some embodiments, the substrate(s) may be subjected to a reactive gas plasma in a separate portion of a sputtering chamber in step 1106. Unlike the sputtering gas (typically an inert gas like argon), the reactive gas may include oxygen or nitrogen to name a few examples. In some embodiments, in step 1108, the exposure to the reactive gas causes the sputtered material on the substrates to oxidize or nitrify, thus forming an oxide or nitride of the material. For example, an aluminum film may become aluminum oxide (Al₂O₃) or aluminum nitride (AlN). In another example, a silicon film may become silicon dioxide (SiO₂) or silicon nitride (Si₃N₄).

Steps 1102, 1104, and 1108 may be controlled to produce a desired coating layer on the substrate(s). In some embodiments, the coating layer may be a scratch resistant coating layer. Exemplary materials used in the scratch resistant coating layer may include an inorganic carbide, nitride, oxide, diamond-like material, or a combination thereof.

In some embodiments, the scratch resistant coating layer may include a multilayer structure of aluminum oxynitride (AlON) and silicon dioxide (SiO₂). In some embodiments, the scratch resistant coating layer may include a metal oxide layer, a metal nitride layer, a metal carbide layer, a metal boride layer or a diamond-like carbon layer. Example metals for such an oxide, nitride, carbide or boride layer include boron, aluminum, silicon, titanium, vanadium, chromium, yttrium, zirconium, niobium, molybdenum, tin, hafnium, tantalum, and tungsten. In some embodiments, the coating layer may include an inorganic material. Non-limiting example inorganic layers include aluminum oxide and zirconium oxide layers.

In some embodiments, the scratch resistant coating layer may include a scratch resistant coating layer as described in U.S. Pat. No. 9,328,016, issued on May 3, 2016, which is hereby incorporated by reference in its entirety by reference thereto. In some embodiments, the scratch resistant coating layer may include a silicon-containing oxide, a silicon-containing nitride, an aluminum-containing nitride (e.g., AlN and AlₓSi_{y}N), an aluminum-containing oxy-nitride (e.g., AlOₓN_{y} and SiᵤAlᵥOₓN_{y}), an aluminum-containing oxide or combinations thereof. In some embodiments, the scratch resistant coating layer may include transparent dielectric materials such as SiO₂, GeO₂, Al₂O₃, Nb₂O₅, TiO₂, Y₂O₃ and other similar materials and combinations thereof. In some embodiments, the scratch resistant coating layer may include a scratch resistant coating layer as described in U.S. Pat. No. 9,110,230, issued on Aug. 18, 2015, which is hereby incorporated by reference in its entirety by reference thereto. In some embodiments, the scratch resistant coating layer may include one or more of AlN, Si₃N₄, AlOₓN_{y}, SiOₓN_{y}, Al₂O₃, SiₓC_{y}, SiₓO_{y}C_{z}, ZrO₂, TiOₓN_{y}, diamond, diamond-like carbon, and SiᵤAlᵥOₓN_{y}. In some embodiments, the scratch resistant coating layer may include a scratch resistant coating layer as described in U.S. Pat. No. 9,359,261, issued on Jun. 7, 2016, or U.S. Pat. No. 9,335,444, issued on May 10, 2016, both of which are hereby incorporated by reference in their entirety by reference thereto.

In some embodiments, the coating layer may be an anti-reflective coating layer. Exemplary materials suitable for use in the anti-reflective coating layer include: SiO₂, Al₂O₃, GeO₂, SiO, AlOₓN_{y}, AlN, SiNₓ, SiOₓN_{y}, SiᵤAlᵥOₓN_{y}, Ta₂O₅, Nb₂O₅, TiO₂, ZrO₂, TiN, MgO, MgF₂, BaF₂, CaF₂, SnO₂, HfO₂, Y₂O₃, MoO₃, DyF₃, YbF₃, YF₃, CeF₃, polymers, fluoropolymers, plasma-polymerized polymers, siloxane polymers, silsesquioxanes, polyimides, fluorinated polyimides, polyetherimide, polyethersulfone, polyphenylsulfone, polycarbonate, polyethylene terephthalate, polyethylene naphthalate, acrylic polymers, urethane polymers, polymethylmethacrylate, and other materials cited above as suitable for use in a scratch resistant layer. An anti-reflection coating layer may include sub-layers of different materials.

In some embodiments, the anti-reflection coating layer may include a hexagonally packed nanoparticle layer, for example but not limited to, the hexagonally packed nanoparticle layers described in U.S. Pat. No. 9,272,947, issued Mar. 1, 2016, which is hereby incorporated by reference in its entirety by reference thereto In some embodiments, the anti-reflection coating layer may include a nanoporous Si-containing coating layer, for example but not limited to the nanoporous Si-containing coating layers described in WO2013/106629, published on Jul. 18, 2013, which is hereby incorporated by reference in its entirety by reference thereto. In some embodiments, the anti-reflection coating may include a multilayer coating, for example, but not limited to the multilayer coatings described in WO2013/106638, published on Jul. 18, 2013; WO2013/082488, published on Jun. 6, 2013; and U.S. Pat. No. 9,335,444, issued on May 10, 2016, all of which are hereby incorporated by reference in their entirety by reference thereto.

In some embodiments, the coating layer may be an easy-to-clean coating layer. In some embodiments, the easy-to-clean coating layer may include a material selected from the group consisting of fluoroalkylsilanes, perfluoropolyether alkoxy silanes, perfluoroalkyl alkoxy silanes, fluoroalkylsilane-(non-fluoroalkylsilane) copolymers, and mixtures of fluoroalkylsilanes. In some embodiments, the easy-to-clean coating layer may include one or more materials that are silanes of selected types containing perfluorinated groups, for example, perfluoroalkyl silanes of formula (R_{F})_{y}Si_{X4-y}, where RF is a linear C6-C₃₀ perfluoroalkyl group, X═CI, acetoxy, —OCH₃, and —OCH₂CH₃, and y=2 or 3. The perfluoroalkyl silanes can be obtained commercially from many vendors including Dow-Corning (for example fluorocarbons 2604 and 2634), 3MCompany (for example ECC-1000 and ECC-4000), and other fluorocarbon suppliers such as Daikin Corporation, Ceko (South Korea), Cotec-GmbH (DURALON UltraTec materials) and Evonik. In some embodiments, the easy-to-clean coating layer may include an easy-to-clean coating layer as described in WO2013/082477, published on Jun. 6, 2013, which is hereby incorporated by reference in its entirety by reference thereto.

In some embodiments, multiple coating layers, of the same or different types, may be sputter coated on the substrate(s). The thickness of the sputtered coating layer(s) may vary based on the parameters used during the sputtering process and the sputtering time, but may be anywhere from 1 nanometer to 1 micrometer.

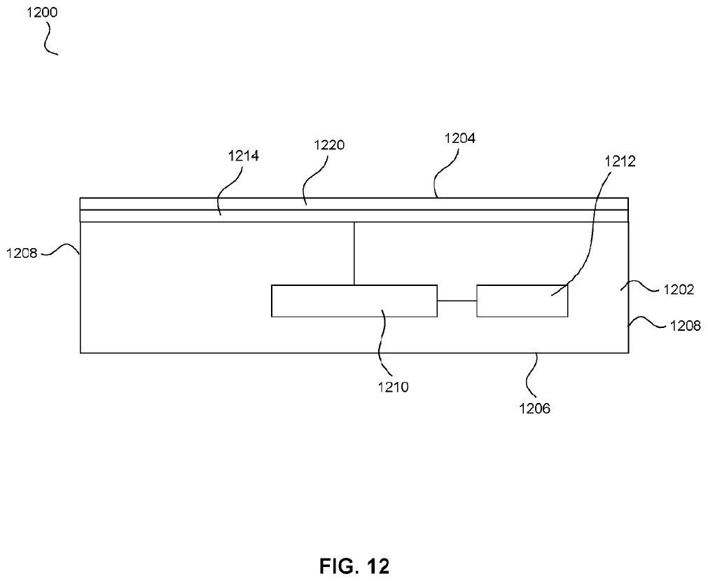

FIG. 12 shows a consumer electronic product 1200 according to some embodiments. Consumer electronic product 1200 may include a housing 1202 having a front (user-facing) surface 1204, a back surface 1206, and side surfaces 1208. Electrical components may be provided at least partially within housing 1202. The electrical components may include, among others, a controller 1210, a memory 1212, and display components, including a display 1214. In some embodiments, display 1214 may be provided at or adjacent to front surface 1204 of housing 1202.

As shown for example in FIG. 12, consumer electronic product 1200 may include a cover glass 1220. Cover glass 1220 may serve to protect display 1214 and other components of electronic product 1200 (e.g., controller 1210 and memory 1212) from damage. In some embodiments, cover glass 1220 may be disposed over display 1214. Cover glass 1220 may be made using a coating process as discussed herein and may be the same as or similar to cover glasses discussed herein (e.g., substrates 204, 350, or 630). Cover glass 1220 may be a 2D, 2.5D, or 3D cover glass. In some embodiments, cover glass 1220 may define front surface 1204 of housing 1202. In some embodiments, cover glass 1220 may define front surface 1204 of housing 1202 and all or a portion of side surfaces 1208 of housing 1202. In some embodiments, consumer electronic product 1200 may include a cover glass defining all or a portion of back surface 1206 of housing 1202.

While various embodiments have been described in the context of coating a cover glass, other glass articles (including glass ceramic articles), for example but not limited to, architectural glass windows, automotive glass windows, camera lenses, and glass ceramics for consumer appliances, may be coated and processed in the same manner as discussed herein.

While various embodiments have been described in the context of a sputter coating deposition process, the substrate supports discussed herein may be employed in other coating processes, including but not limited to chemical vapor deposition (CVD) processes and spray coating process. The substrate supports may provide the same or similar benefits as discussed herein to these coating processes, and others.

As used herein the term “glass” is meant to include any material made at least partially of glass, including glass and glass-ceramics. “Glass-ceramics” include materials produced through controlled crystallization of glass. In embodiments, glass-ceramics have about 30% to about 90% crystallinity. Non-limiting examples of glass ceramic systems that may be used include Li2O×Al2O3×nSiO2 (i.e. LAS system), MgO×Al₂O₃×nSiO2 (i.e. MAS system), and ZnO×Al₂O₃×nSiO2 (i.e. ZAS system).

In one or more embodiments, the amorphous substrate may include glass, which may be strengthened or non-strengthened. Examples of suitable glass include soda lime glass, alkali aluminosilicate glass, alkali containing borosilicate glass and alkali aluminoborosilicate glass. In some variants, the glass may be free of lithia. In one or more alternative embodiments, the substrate may include crystalline substrates such as glass ceramic substrates (which may be strengthened or non-strengthened) or may include a single crystal structure, such as sapphire. In one or more specific embodiments, the substrate includes an amorphous base (e.g., glass) and a crystalline cladding (e.g., sapphire layer, a polycrystalline alumina layer and/or or a spinel (MgAl2O4) layer).

A substrate may be strengthened to form a strengthened substrate. As used herein, the term “strengthened substrate” may refer to a substrate that has been chemically strengthened, for example through ion-exchange of larger ions for smaller ions in the surface of the substrate. However, other strengthening methods known in the art, such as thermal tempering, or utilizing a mismatch of the coefficient of thermal expansion between portions of the substrate to create compressive stress and central tension regions, may be utilized to form strengthened substrates.

Where the substrate is chemically strengthened by an ion exchange process, the ions in the surface layer of the substrate are replaced by—or exchanged with—larger ions having the same valence or oxidation state. Ion exchange processes are typically carried out by immersing a substrate in a molten salt bath containing the larger ions to be exchanged with the smaller ions in the substrate. It will be appreciated by those skilled in the art that parameters for the ion exchange process, including, but not limited to, bath composition and temperature, immersion time, the number of immersions of the substrate in a salt bath (or baths), use of multiple salt baths, additional steps such as annealing, washing, and the like, are generally determined by the composition of the substrate and the desired compressive stress (CS), depth of compressive stress layer (or depth of layer) of the substrate that result from the strengthening operation. By way of example, ion exchange of alkali metal-containing glass substrates may be achieved by immersion in at least one molten bath containing a salt such as, but not limited to, nitrates, sulfates, and chlorides of the larger alkali metal ion. The temperature of the molten salt bath typically is in a range from about 380° C. up to about 450° C., while immersion times range from about 15 minutes up to about 40 hours. However, temperatures and immersion times different from those described above may also be used.

In addition, non-limiting examples of ion exchange processes in which glass substrates are immersed in multiple ion exchange baths, with washing and/or annealing steps between immersions, are described in U.S. Pat. No. 8,561,429, issued on Oct. 22, 2013, by Douglas C. Allan et al., entitled “Glass with Compressive Surface for Consumer Applications,” in which glass substrates are strengthened by immersion in multiple, successive, ion exchange treatments in salt baths of different concentrations; and U.S. Pat. No. 8,312,739, by Christopher M. Lee et al., issued on Nov. 20, 2012, and entitled “Dual Stage Ion Exchange for Chemical Strengthening of Glass,” in which glass substrates are strengthened by ion exchange in a first bath is diluted with an effluent ion, followed by immersion in a second bath having a smaller concentration of the effluent ion than the first bath. The contents of U.S. Pat. Nos. 8,561,429 and 8,312,739 are incorporated herein by reference in their entirety.

While various embodiments have been described herein, they have been presented by way of example only, and not limitation. It should be apparent that adaptations and modifications are intended to be within the meaning and range of equivalents of the disclosed embodiments, based on the teaching and guidance presented herein. It therefore will be apparent to one skilled in the art that various changes in form and detail can be made to the embodiments disclosed herein without departing from the spirit and scope of the present disclosure. The elements of the embodiments presented herein are not necessarily mutually exclusive, but may be interchanged to meet various situations as would be appreciated by one of skill in the art.

Embodiments of the present disclosure are described in detail herein with reference to embodiments thereof as illustrated in the accompanying drawings, in which like reference numerals are used to indicate identical or functionally similar elements. References to “one embodiment,” “an embodiment,” “some embodiments,” “in certain embodiments,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

The examples are illustrative, but not limiting, of the present disclosure. Other suitable modifications and adaptations of the variety of conditions and parameters normally encountered in the field, and which would be apparent to those skilled in the art, are within the spirit and scope of the disclosure.

The term “or,” as used herein, is inclusive; more specifically, the phrase “A or B” means “A, B, or both A and B.” Exclusive “or” is designated herein by terms such as “either A or B” and “one of A or B,” for example.

The indefinite articles “a” and “an” to describe an element or component means that one or at least one of these elements or components is present. Although these articles are conventionally employed to signify that the modified noun is a singular noun, as used herein the articles “a” and “an” also include the plural, unless otherwise stated in specific instances. Similarly, the definite article “the,” as used herein, also signifies that the modified noun may be singular or plural, again unless otherwise stated in specific instances.

As used in the claims, “comprising” is an open-ended transitional phrase. A list of elements following the transitional phrase “comprising” is a non-exclusive list, such that elements in addition to those specifically recited in the list may also be present. As used in the claims, “consisting essentially of” or “composed essentially of” limits the composition of a material to the specified materials and those that do not materially affect the basic and novel characteristic(s) of the material. As used in the claims, “consisting of” or “composed entirely of” limits the composition of a material to the specified materials and excludes any material not specified.

The term “wherein” is used as an open-ended transitional phrase, to introduce a recitation of a series of characteristics of the structure.

Where a range of numerical values is recited herein, comprising upper and lower values, unless otherwise stated in specific circumstances, the range is intended to include the endpoints thereof, and all integers and fractions within the range. It is not intended that the scope of the claims be limited to the specific values recited when defining a range. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed. Finally, when the term “about” is used in describing a value or an end-point of a range, the disclosure should be understood to include the specific value or end-point referred to. Whether or not a numerical value or end-point of a range recites “about,” the numerical value or end-point of a range is intended to include two embodiments: one modified by “about,” and one not modified by “about.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art.

Directional terms as used herein—for example up, down, right, left, front, back, top, bottom—are made only with reference to the figures as drawn and are not intended to imply absolute orientation.

The present embodiment(s) have been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

It is to be understood that the phraseology or terminology used herein is for the purpose of description and not of limitation. The breadth and scope of the present disclosure should not be limited by any of the above-described exemplary embodiments, but should be defined only in accordance with the following claims and their equivalents.

1. A sputtering device comprising:
a chamber;
a target disposed within the chamber;
a rotating drum comprising a drum frame disposed within the chamber; and
a substrate support comprising a carrier coupled to the drum frame and a fixture for holding a substrate, the fixture coupled to a target-facing surface of the carrier,
wherein at least the target-facing surface of the carrier consists essentially of a non-aluminous and non-magnetic metallic material.

2. The sputtering device of claim 1, wherein the carrier comprises a clamp coupled to the target-facing surface of the carrier for clamping the fixture onto the carrier.

3. The sputtering device of claim 2, wherein the clamp consists essentially of a non-aluminous and non-magnetic metallic material.

4. The sputtering device of claim 1, wherein the fixture consists essentially of a non-aluminous and non-magnetic metallic material.

5. The sputtering device of claim 1, wherein the carrier consists essentially of a non-aluminous and non-magnetic metallic material.

6. The sputtering device of claim 1, wherein the substrate support consists essentially of a non-aluminous and non-magnetic metallic material.

7. The sputtering device of claim 1, wherein at least the target-facing surface of the carrier consists essentially of stainless steel 316.

8. The sputtering device of claim 1, wherein at least 90 volume percent of the substrate support consists essentially of a non-aluminous and non-magnetic metallic material.

9. The sputtering device of claim 1, wherein the carrier comprises a plate defining the target-facing surface of the carrier.

10. The sputtering device of claim 9, wherein the plate is a hollow plate.

11. The sputtering device of claim 9, wherein the plate consists essentially of stainless steel 316 having no magnetic charge.

12. The sputtering device of claim 1, wherein the fixture comprises a bottom plate and a top plate coupled to the bottom plate, for clamping a substrate therebetween, and
wherein the top plate and the bottom plate consist essentially of a non-aluminous and non-magnetic metallic material.

13. The sputtering device of claim 1, wherein the fixture comprises a vacuum plate comprising a plurality of through holes and a double sided adhesive layer, disposed over a portion of a top surface of the vacuum plate, for adhering a substrate thereto, and
wherein the vacuum plate consists essentially of a non-aluminous and non-magnetic metallic material.

14. The sputtering device of claim 1, further comprising a plurality of fixtures coupled to the target-facing surface of the carrier, at least one fixture for holding at least one substrate, and wherein the carrier comprises one or more clamps for clamping the fixtures onto the carrier.

15. The sputtering device of claim 1, wherein at least the target-facing surface of the carrier consists essentially of a material selected from the group consisting of: a copper alloy and a titanium alloy.

16. The sputtering device of claim 1, wherein at least the target-facing surface of the carrier consists essentially of a material comprising a coefficient of thermal expansion equal to 21.6 ppm/° C. or less at 20° C.

17. The sputtering device of claim 1, wherein at least the target-facing surface of the carrier consists essentially of a material comprising a coefficient of thermal expansion equal to 18 ppm/° C. or less at 20° C.

18. The sputtering device of claim 1, wherein the carrier weighs 100 kilograms or less.

19. A sputtering method comprising:
coupling a substrate to a carrier;
coupling the carrier to a rotating drum comprising a drum frame, the drum frame disposed within a chamber of a sputtering device, the chamber comprising a target disposed with the chamber; and
coating the substrate with a coating layer,
wherein at least a target-facing surface of the carrier consists essentially of a non-aluminous and non-magnetic metallic material.

20. The sputtering method of claim 19, wherein the sputtering method is a drum sputtering method.

21. The sputtering method of claim 19, wherein the sputtering method is a magnetron sputtering method.

22. The sputtering method of claim 19, wherein coupling the substrate to the carrier comprises coupling the substrate to a fixture and coupling the fixture to the carrier, and wherein the fixture consists essentially of a non-aluminous and non-magnetic metallic material comprising a coefficient of thermal expansion that is equal to 18 ppm/° C. or less at 20° C.

23. The sputtering method of claim 19, further comprising etching the target-facing surface of the carrier, with a strong acid and a strong base to remove coating layer material from the target-facing surface, after one or more substrate coating processes.

24. A sputtering device comprising:
a chamber;
a target disposed within the chamber; and
a substrate support disposed within the chamber, the substrate support comprising a carrier and a fixture for holding a substrate, the fixture coupled to a target-facing surface of the carrier,
wherein at least the target-facing surface of the carrier consists essentially of a non-aluminous and non-magnetic metallic material.

25. An article comprising a coated cover glass, the coated cover glass made by the sputtering method comprising:
coupling a cover glass to a carrier;
coupling the carrier to a rotating drum comprising a drum frame, the drum frame disposed within a chamber of a sputtering device, the chamber comprising a target disposed with the chamber; and
coating the cover glass with a coating layer,
wherein at least a target-facing surface of the carrier consists essentially of a non-aluminous and non-magnetic metallic material comprising a coefficient of thermal expansion that is equal to 18 ppm/° C. or less at 20° C.

26. The article of claim 25, wherein the article is a consumer electronic product, the consumer electronic product comprising:
a housing comprising a front surface, a back surface and side surfaces;
electrical components provided at least partially within the housing, the electrical components comprising at least a controller, a memory, and a display, the display being provided at or adjacent the front surface of the housing; and
the coated cover glass, wherein the coated cover glass is disposed over the display.
